(19) United States
(12) Patent Application Publication
(10) Pub. No.: US 2004/0038452 A1
(43) Pub. Date: Feb. 26, 2004

(54) Connection between semiconductor unit and device carrier

(75) Inventor: Han-Ping Pu, Taipei County (TW)

Correspondence Address: KLARQUIST SPARKMAN, LLP, 121 SW SALMON STREET, SUITE 1600, PORTLAND, OR, 97204, US

(73) Assignee: Siliconware Precision Industries Co., Ltd.

(21) Appl. No.: 10/650,258

(22) Filed: Aug. 27, 2003

Related U.S. Application Data
(63) Continuation-in-part of application No. 09/952,651, filed on Sep. 13, 2001, now abandoned.

(30) Foreign Application Priority Data
May 30, 2001 (TW) 90112991

(51) Int. Cl. H01L 21/44; H01L 21/48

(52) U.S. Cl. 438/116

(57) ABSTRACT

The present invention provides methods/interconnection portions for connecting at least a semiconductor unit such as chip to at least a device carrier (such as lead frame) lacking good mechanism for limiting solder flowing of melted metal. The methods are characterized by forming at least a device carrier bump jutting out from a metal surface of the device carrier lacking good mechanism thereon for limiting solder flowing of melted metal, and forming at least a chip bump which melts for the device carrier bump to approach the electrode of the chip and have an end on the electrode of the chip. The chip bump melts to surround and adhere to the device carrier bump, and to have one end on the metal surface of the device carrier, resulting in an interconnection portion including a first part and a second part both having one end on the metal surface and another end on the chip.

### CROSS REFERENCE TO RELATED APPLICATION

This is a continuation-in-part of prior, pending application Ser. No. 09/952,651, filed on Sep. 13, 2001, which is incorporated herein by reference.

### FIELD

The present invention relates generally to arts of connecting at least a semiconductor unit, via at least a bump, to at least a device carrier lacking good mechanism for limiting solder flowing of the bump when melted, and particularly to arts of connecting a chip to a flat metal surface of a device carrier such as a lead frame.

### BACKGROUND

In conventional arts of connecting a chip via bumps to a lead frame or a device carrier having neither connection pads nor insulation layer thereon, reflow soldering (heat applying) process always results in bumps' collapses of inconsistent height due to disunity of wetty (or solder flowing) on the surface of such a device carrier, because of the lack of mechanism to limit the solder flowing. The collapses of bumps resulting from the reflow soldering process may even lead to the chip contacting the lead frame.

In contrast, when connecting a chip via bumps to a device carrier having connection pads (or electrodes each surrounded by insulation material), the solder flowing in the reflow soldering process is limited to pad surface or by insulation material, and the collapses of bumps resulting from reflow soldering process is not so serious. For example, according to U.S. Pat. No. 5,611,481, pad 5 of circuit board 6, and pads 15A-15F of circuit board 16, as well as pads 25A-25F of circuit board 26 thereof, are formed for soldering connection, and usually surrounded by insulation layer of the circuit board. Also for example, according to U.S. Pat. No. 5,796,591, electrode 20 for soldering connection with chip 30 is exposed and surrounded by insulation layer 22. A pad may even be required to provide adhesive tendency for molten metal to adhere thereto, as suggested by U.S. Pat. No. 5,611,481, which better limits solder flowing of a melted bump to the surface of the pad. These prior arts as well as the other related conventional technologies, though good for connecting a chip via bumps to a device carrier having connection pads (or electrodes each surrounded by insulation material), are far from ideal for connecting a chip via bumps to a device carrier (a lead frame, for example) having no mechanism such as connection pads (or electrodes each surrounded by insulation material) for limiting solder flowing of a melted bump.

Although U.S. Pat. No. 6,184,573 and Taiwanese patent 366,576 suggested schemes of spreading a solder mask layer on a lead frame and forming openings in the solder mask layer, in order to control collapse height when bumps melt (i.e., to restrict solder flowing), so that bump collapse height may more likely be consistent after reflow soldering. The process of spreading the solder mask layer on the lead frame and forming openings therein, however, is quite complicate and expensive, and the light resolution of solder mask material is so poor that the accuracy promotion of forming openings in the solder mask is not realistic, i.e., the sizes of the openings are unlikely to be consistent. Furthermore, in case the bump is relatively small (diameter of 120˜130 μm for example), it is even more difficult to form openings with sufficient accuracy. The inaccuracy of the opening size will inevitably result in the inconsistency of the sizes of the openings, leading to inconsistency of collapse of the bumps, and to extreme difficulty of reliably controlling the quality of the electrical connection between the chip and the lead frame. On the other band, the bumps with inconsistent size of solder joint area provide inconsistent thermal stress due to different thermal expansion coefficient between the chip and the lead frame, resulting in application uncertainty of a chip package. Although Laser technology may be used to form relatively delicate openings, it must be so implemented as to form the openings one by one, leading to unreasonable time consumption and manufacturing cost. Even worse is the formation of voids between the chip and the lead frame when molding the chip package, as a result of inconsistent magnitude of the gap between the chip and the lead frame caused by inconsistent collapse of the bumps. The voids contribute to poor reliability of quality of a chip package. It can be seen now that the scheme of forming openings in a solder mask layer on a lead frame according to the two prior arts are still not ideal for packaging chips, and a further better art for connecting a chip to a lead frame via bumps is expected by related industries. The present invention is therefore developed to fulfill the expectation.

Due to the difficulty for conventional arts to provide a lead frame package or the like with fine pitch which is expected by related industries, as can be understood from the above description, the present invention further discloses a scheme of forming bumps on lead frames by plating technology, in order to realize chip packages with fine pitch.

A conventional method for connecting a chip to a flat metal surface of a lead frame via bumps is described hereinafter by referring to FIG. 1a and FIG. 1b. As shown in FIG. 1a, chip 21 connects a flat metal surface 82 of an inner lead 81 of lead frame 101 via bump 31, wherein bump 31 collapses in reflow soldering, with its height 28 shown in FIG. 1a reduced to 29 shown in FIG. 1b. Furthermore, collapses of different bumps are not consistent due to disunity of wettability on the flat metal surface 82 of the lead frame. The above Taiwanese patent 366576 and U.S. Pat. No. 6,184,573 disclosed some schemes intended for solutions to the bump collapse or the inconsistency of bump collapses inherent in conventional arts of connecting a chip to a lead frame via bumps. The prior schemes are characterized by spreading a solder mask layer 22 on the flat metal surface 82 of lead frame 101 (as show in FIG. 1c), and forming opening 23 for bump 31 to contact the flat metal surface 82, in order to restrict the bump collapse. However, the technology to spread the solder mask layer on the metal surface of a lead frame is not yet mature, the methods suggested by the two prior arts for connecting chip 21 to lead frame 101 via bumps 31 are far from ideal, leading to the development of the present invention for realizing ideal methods of connecting at least a chip to a lead frame via bumps.

### SUMMARY

An object of the present invention is to provide a solution to the problem of inconsistency of bumps' collapses faced by conventional processes of connecting a chip via bumps to a lead frame or any device carrier having no mechanism for limiting solder flowing of molten bump.

Another object of the present invention is to provide alternative arts for related industries to avoid high cost and complicated steps resulting from adopting the process of forming openings in solder mask layer which is intended for avoiding the disunity of bumps' collapses when connecting a chip to a lead frame via bumps.

A further object of the present invention is to provide a method of connecting a semiconductor unit via bumps to a device carrier having no mechanism for limiting solder flowing of molten bump, in which a semiconductor package with fine pitch can be realized by steps featuring stencil printing or plating to form bumps on the device carrier.

Another further object of the present invention is to provide a method of connecting a semiconductor unit via bumps to a device carrier having no mechanism for limiting solder flowing of molten bump, which features stencil printing or plating for forming, on the device carrier, the bumps with height finely controllable and melting point (melting temperature) higher than that of chip bump, thereby the gap between the semiconductor unit and the device carrier can be determined by the height of the bumps formed on the device carrier, and bumps' collapses can be finely controlled, and molding process for the chip package can be immunized against void formation.

The other further object of the present invention is to provide a method of connecting a semiconductor unit via bumps to a device carrier having no mechanism for limiting solder flowing of molten bump, which features stencil printing or plating for forming bumps on the device carrier, thereby the semiconductor unit connects the device carrier via the bumps formed on the device carrier and having height and/or size finely controllable, resulting in finely controllable solder joint area for ensuring the quality of electrical connection between the semiconductor unit and the device carrier, and for avoiding the unevenness of thermal stress resulting from the difference in thermal expansion coefficient between the semiconductor unit and the device carrier.

The present invention may be represented by a method for connecting at least a semiconductor unit to at least a device carrier, wherein the semiconductor unit includes at least an electrode and the device carrier is enclosed by a metal surface or includes nothing but a body and a metal surface, i.e., the device carrier has no mechanism thereon for limiting solder flowing of molten bump. For example, the device carrier has neither connection pad nor insulation material on its surface. The method according to the present invention comprises:

forming at least a bump of a first type, the bump of the first type jutting out from the electrode of the semiconductor unit and having a first melting point (melting temperature);

forming at least a bump of a second type, the bump of the second type jutting out from the metal surface and having a second melting point higher than the first melting point;

arranging the semiconductor unit and the device carrier in such a way that the bump of the first type and the bump of the second type face and approach (or contact) each other;

providing heat until the bump of the first type reaches a temperature at least equal to the first melting point, while the bump of the second type remains at a temperature lower than the second melting point, i.e., heat is so provided that the bump (jutting out from the electrode of the semiconductor unit) with lower melting point melts while the bump (jutting out from the metal surface) with higher melting point remains; and

letting the bump of the first type (the one jutting out from the electrode of the semiconductor unit) melt for the bump of the second type (the one jutting out from the metal surface) to approach the electrode of the semiconductor unit, and the melted bump of the first type flow to surround the bump of the second type and approach the metal surface, until the bump of the second type having one end on the metal surface has another end on the electrode of the semiconductor unit, and the melted bump of the first type flow to reach a first end of the bump of the second type, wherein the first end of the bump of the second type is on the metal surface, thereby the semiconductor unit connects the device carrier via the bump jutting out from the metal surface which is free from requiring mechanism thereon for limiting solder flowing of the melted bump. Now both the bumps of the first type and the second type have one end on the semiconductor unit and another end on the metal surface, resulting in the formation of an interconnection portion including a first part and a second part, the first part having one end on the metal surface and another end on the semiconductor unit, the second part having one end on the metal surface and another end on the electrode of the semiconductor unit, the first part being so composed that its melting point is lower than that of the second part, and is able to surround and adhere to the surface of the second part when it melts to flow along the surface of the second part. Because the bump of the second type does not melt (i.e., remains in size) and has one end on the metal surface and another end on the electrode of the semiconductor unit, the distance between the electrode of the semiconductor unit and the metal surface is determined according to the size of the bump of the second type, i.e., the bump (jutting out from the electrode of the semiconductor unit) with lower melting point melts to flow along the surface of the bump (jutting out from the metal surface) with higher melting point, and to gradually surround the bump of higher melting point, the bump of the second type having one end on the metal surface may approach and contact the semiconductor unit, thereby the distance between the semiconductor unit and the chip carrier is substantially determined by the size of the bump of the second type. For example, if the bump of the second type juts out from the metal surface for a height, the distance between the semiconductor unit and the metal surface is determined according to the height. Obviously the bump (jutting out from the electrode of the semiconductor unit) with lower melting point will have one end on the metal surface when it flows along the surface of the bump of the second type to reach the metal surface. Based on the method provided by the present invention, a semiconductor unit can be connected via bumps to a device carrier which is free from requiring mechanism (such as connection pad or insulation material) thereon for limiting solder flowing of melted bump.

In the above process of providing heat, the bump with lower melting point melts while the bump with higher melting point remains (height and/or size of the bump remains unchanged, for example), the bump with lower melting point melts to allow the bump with higher melting point to approach, or even contact the electrode of the semiconductor unit.

According to the above method provided by the present invention, the bump with higher melting point (melting temperature) does not melt in the step of providing heat, and therefore does not collapse, resulting in the elimination of inconsistency of bumps' collapses inherent in conventional art of connecting a chip to a lead frame via bumps. Furthermore the bump of higher melting point which juts out from the metal surface of a device carrier may approach and contact the semiconductor unit, thereby the distance between the semiconductor unit and the chip carrier is substantially determined by the size of the bump of the second type which always maintains the same shape/size, resulting in controllable distance between the semiconductor unit and the chip carrier.

According to the present invention, the connection between a semiconductor unit and a device carrier having no mechanism thereon for limiting solder flowing of molten bump, as can be seen from above, is characterized by an interconnection portion including a first part and a second part, the second part being a bump of the second type having a second melting point, the first part formed by melting a bump of the first type having a first melting point lower than the second melting point. The melted bump of the first type flows along the surface of the bump of the second type (i.e., the second part of the interconnection portion) to surround the bump of the second type, and becomes the first part of the interconnection portion when cooling down. The solder wettability between the melted bump of the first type and the bump of the second type is controlled by the bump of the second type, thereby the melted bump of the first type surrounds the bump of the second type instead of spreading onto the metal surface of the device carrier. The bump of the second type which has one end on the metal surface of the device carrier, approaches the electrode of semiconductor unit when the bump of the first type melts, and eventually has another end on the electrode of the semiconductor unit, becoming the second part of the interconnection portion. As a result, the first part of the interconnection portion has one end on the metal surface and another end on the semiconductor unit, and the second part of the interconnection portion has one end on the metal surface and another end on the electrode of the semiconductor unit.

It can be seen now the present invention may also be represented by an electronic package comprising:

a device carrier (a lead frame, for example) enclosed by a metal surface or including a metal surface without mechanism thereon for limiting solder flowing of molten metal;

at least a semiconductor unit including at least an electrode; and

at least an interconnection portion including a first part and a second part, the first part having one end on the metal surface and another end on the semiconductor unit, the second part having one end on the metal surface and another end on the electrode of the semiconductor unit, the first part surrounding and adhering to the second part, and being composed to have a melting point lower than that of the second part. For example, the first part may contain more tin than lead while the second part contain more lead than tin, thereby the melting point of the first part is lower than that of the second part. Also the first part and the second part may be respectively so composed as to let the solder wettability between the first part and the second part be controlled by the second part, thereby the first part, when in a melting state or liquid (or fluid) state, surrounds and adheres to the second part instead of spreading onto the metal surface of the device carrier. The interconnection portion of the electronic package provided by the present invention may be formed to either electrically or mechanically connect the device carrier and the semiconductor unit, or formed to electrically and mechanically connect the device carrier and the semiconductor unit.

In this disclosure, the bump formed jutting out from a metal surface of a lead frame is called “lead frame bump”, and the bump formed jutting out from an electrode of a chip is called “chip bump”.

Because the lead frame bump may be formed by stencil printing or plating, its size and height can be finely controlled, i.e., the gap (or distance) which is between the chip and the lead frame and which is determined by the height of the lead frame bump according the present invention, can be finely controlled regardless of the step of providing heat such as reflow soldering which is indispensable to the art of connecting a chip to a lead frame via bump(s).

It can be understood now that the art based on the present invention features:

1. Immunizing a device carrier against requiring mechanism of limiting solder flowing of melted metal.

2. Eliminating the problem of inconsistency of bumps' collapses faced by conventional art of connecting a chip to a lead frame via bumps.

3. Incurring no such problems of high cost and complicated manufacturing process as does the arts which are based on forming openings in a solder mask layer on a lead frame in order to attempt avoiding the inconsistency of bumps' collapses.

4. Forming lead frame bumps by stencil printing or plating, thereby at least a chip can be ideally connected to the lead frame through the joint connection of chip bumps and the lead frame bumps which do not collapse in heating process, whereby chip packages with fine pitch can be realized.

5. By stencil printing or plating, lead frame bumps may be formed with melting point (melting temperature) higher than chip bumps, with height finely controllable; and based on the present invention, lead frame bumps may approach the chip until it has one end on the electrode of the chip, thereby the gap size between the chip and the lead frame is solely determined by the height of the lead frame bumps, leading to no collapse or finely controlled collapses, immunizing molding process of the chip package against void effect resulting from the inconsistency of bumps' collapses faced by conventional art of connecting a chip to a lead frame via bumps.

6. By stencil printing or plating, lead frame bumps are formed with melting point (melting temperature) higher than chip bumps, and with height as well as size finely controlled, thereby the area of solder joint of each of the lead frame bumps can be finely controlled, leading to reliable quality of electrical connection between the chip and the lead frame, also leading to avoiding unevenness of thermal stress resulting from the difference in thermal expansion coefficient between the chip and the lead frame.

In the above method developed by the present invention, the step of providing heat is to reflow solder the bump of lower melting point. Better wettability between two bumps contacting each other may be achieved by spreading flux on the surface of the bump, thereby better reflow soldering can be achieved. The way for two bumps to face and approach (or contact) each other in the method developed by the present invention is not necessarily limited to vertical direction, it may also be in horizontal direction such as left-right, or in any direction as long as the following condition stands: the bump of lower melting point melts and flows along the surface of the bump of higher melting point during the step of reflow soldering the bump of lower melting point, resulting in the bump of higher melting point being surrounded by the melted bump of lower melting point (the bump of higher melting point does not melt), thereby the bump of higher melting point which juts out from a metal surface of a device carrier eventually reaches the electrode of a semiconductor unit (i.e., the bump of higher melting point eventually has another end on the electrode of the semiconductor unit), and the device carrier the semiconductor unit are finally connected by the bump of higher melting point. In case the direction for two bumps to face and approach (or contact) each other is vertical (i.e., one is on the top of the other), the force due to gravity of the one on the top (i.e., the weight of the one on the top) naturally serves as a force for the two bumps to contact each other with pressure, leading to the bump (not melted) of higher melting point being gradually surrounded by the bump of lower melting point when the bump of lower melting point is melting, without need of another external force. In case the direction for the two bumps to contact is not vertical, an external force may be applied in such a way that the melted bump gradually flows along the surface of the bump (not melted) of higher melting point, until the semiconductor unit and the device carrier are connected by the bump of higher melting point.

In the above method developed by the present invention, the semiconductor unit may include a semiconductor connection surface with the bump of first type seated thereon. An external force may be applied in such a way that the bump of first type and the bump of second type face and contact each other, with the semiconductor connection surface and the metal surface face and approximately parallel each other.

Based on the method provided by the present invention, at least two semiconductor units (such as chips) may be connected to a device carrier (such as lead frame) via bumps. The semiconductor unit includes at least an electrode, and the device carrier includes or is enclosed by a first metal surface and a second metal surface both in different directions (one is upward while the other downward, for example). The method provided by the present invention for connecting at least two such chips to a device carrier via bumps may comprise:

forming at least a bump of a first type on each of the chips, the bump of the first type jutting out from the electrode of the chip and having a first melting point;

forming at least a bump of a second type jutting out from the first metal surface and having a second melting point higher than the first melting point;

forming at least a bump of a second type jutting out from the second metal surface and having the second melting point;

arranging these two chips and the device carrier in such a way that the bumps of the first type formed on a first chip face and approach (or contact) the bumps jutting out from the first metal surface, while the bumps of the first type formed on a second chip face and approach (or contact) the bumps jutting out from the second metal surface;

providing heat until the bumps of the first type reach a temperature at least equal to the first melting point, while the bumps of the second type remains at a temperature lower than the second melting point; and

letting the bump of the first type melt for the bumps of the second type to respectively approach the electrodes of the chips, until the bump jutting out from the first metal surface (having one end on the first metal surface) has another end on the first chip (specifically the electrode of the first chip), and the bump jutting out from the second metal surface (having one end on the second metal surface) has another end on the second chip (specifically the electrode of the second chip), thereby the distance between the metal surface and the electrode of each of the chips is determined according to the size of the bump jutting out from the metal surface, and the semiconductor units are thus connected to the device carrier via the bumps jutting out from the metal surfaces which are free from requiring neither insulation material nor connection pad thereon.

When providing heat, if a force is applied in such a way that the semiconductor units tend to move toward the device carrier, the bump with lower melting point will disperse more quickly to flow along the surface of the bump which remains due to its higher melting point. According to the art provided by the present invention, the bump with higher melting point shall not collapse because it does not melt as a result of its higher melting point which is higher than the temperature reached by providing heat, leading to elimination of problems arising from disunity of bumps' collapses inherent in conventional art of connecting a semiconductor unit to a device carrier having no mechanism to limit solder flowing of melted bump.

A method further provided by the present invention for connecting at least a semiconductor unit (such as a chip) to a device carrier (such as a lead frame), wherein the chip includes at least an electrode, and the device carrier includes or is enclosed by a metal surface. The method may comprise:

forming at least a device carrier bump on the metal surface of the device carrier;

arranging the device carrier, the chip, and a connection medium in such a way that the connection medium is sandwiched between the device carrier bump and the electrode of the chip, wherein the melting point of the connection medium is lower than that of the device carrier bump and the electrode of the chip; and

providing heat in such a way that the connection medium melts while the device carrier bump and the electrode of the chip remain, until the connection medium melts for the device carrier bump to approach the electrode of the chip and finally have one end on the electrode of the chip, and the connection medium flows along the surface of the device carrier bump to have one end on the metal surface, i.e., the chip and the device carrier is connected by at least an interconnection portion including a first part and a second part, wherein the first part is the melted connection medium having one end on the metal surface and another end on the chip, the second part is the device carrier bump having one end on the metal surface and another end on the electrode of the chip, the first part surrounds and adheres to the second part, and is composed to have a melting point lower than that of the device carrier bump and the chip.

Obviously the method provided by the present invention for connecting a semiconductor unit (such as a chip) to a device carrier (such as a lead frame) via bump(s) may also be embodied in a way similar to the above steps: if at least a chip bump has been formed on a chip, sandwich a connection medium between the chip bump and the device carrier, and provide heat in such a way that the connection medium melts while the chip bump and the device carrier do not melt, until the chip and the device carrier is connected by at least an interconnection portion including a first part and a second part, wherein the first part is the melted connection medium having one end on the metal surface and another end on the chip, the second part is the chip bump having one end on the metal surface and another end on the electrode of the chip, the first part surrounds and adheres to the second part, and is composed to have a melting point lower than that of the chip bump and the device carrier.

The present invention may best be understood through the following description with reference to the accompanying drawings, in which:

### BRIEF DESCRIPTION OF THE DRAWINGS

FIGS. 1a and 1b show a typical conventional art of connecting a chip to a lead frame via at least a bump.

FIGS. 2-6 show an embodiment of an electronic package/a method provided by the present invention to include/to form an interconnection portion connecting a chip to a device carrier.

FIGS. 7a and 7b show an embodiment of an electronic package/a method provided by the present invention to include/to form interconnection portions connecting at least two semiconductor units to a device carrier.

FIGS. 8-12 show a further embodiment of an electronic package/a method provided by the present invention to include/to form an interconnection portion connecting a semiconductor unit to a device carrier.

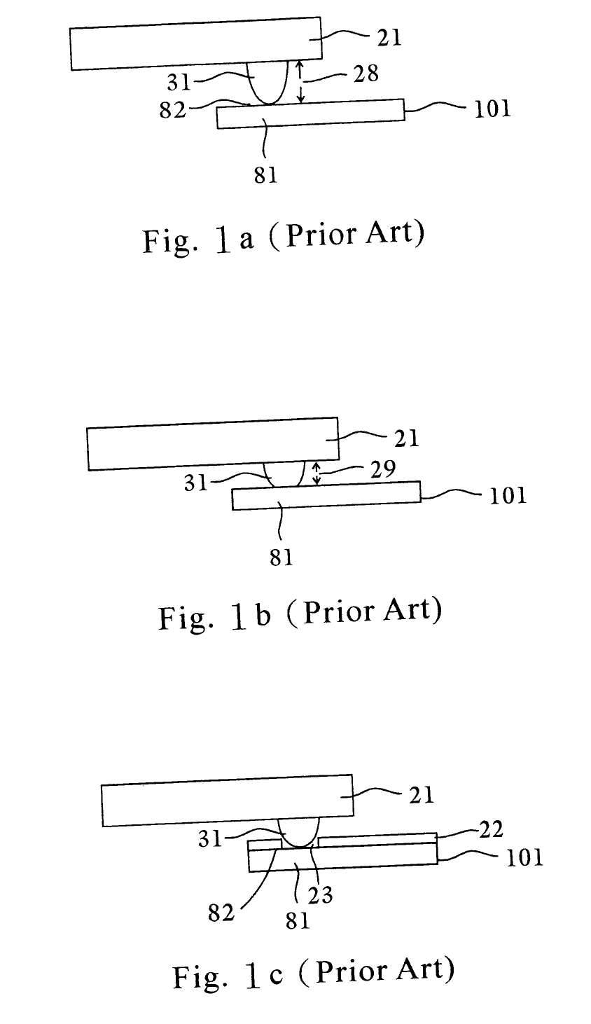

### DETAILED DESCRIPTION OF THE PREFERRED EMBODIMENTS

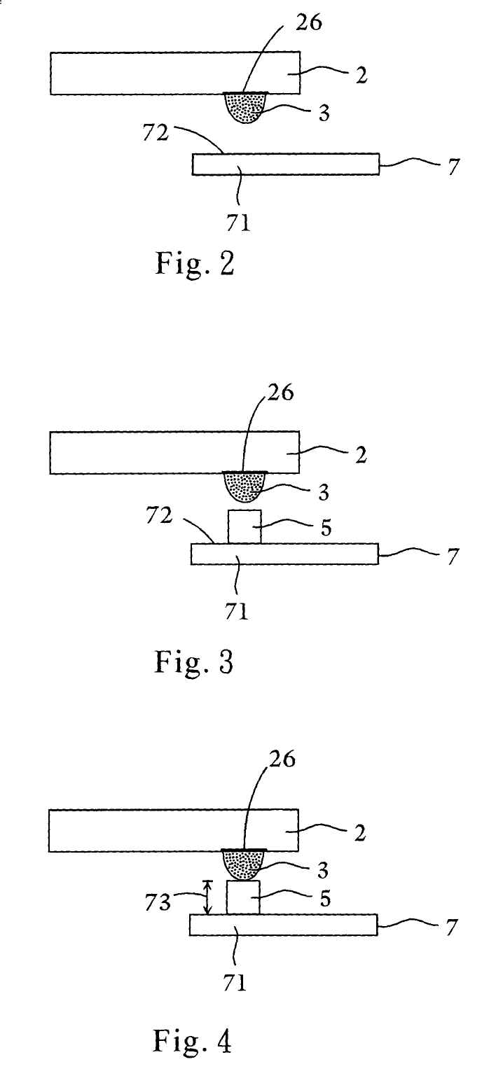

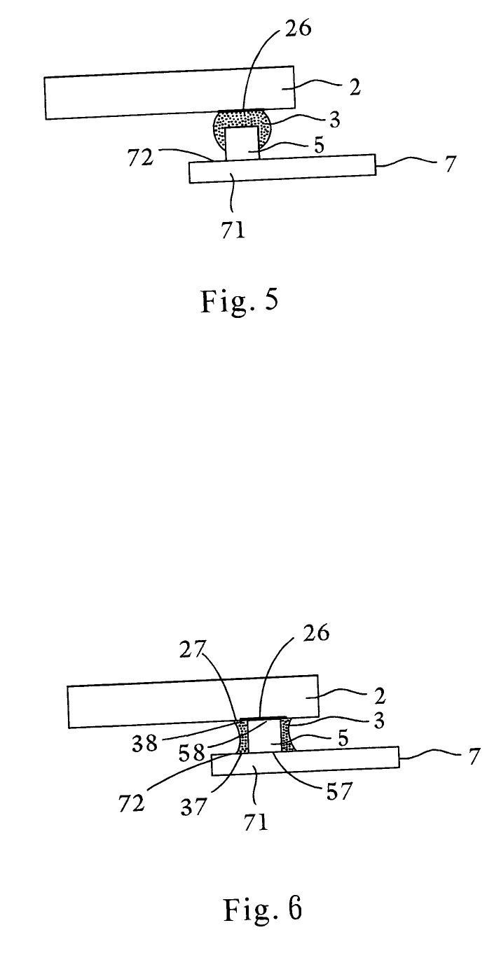

FIGS. 2-6 show a first embodiment of the method provided by the present invention for connecting a semiconductor unit (such as chip 2 in the figures), via at least a bump, to a device carrier (such as lead frame 7 in the figures) having no mechanism for limiting solder flowing of melted metal, wherein the chip 2 includes at least an electrode 26 and the lead frame 7 includes an inner lead 71 which includes or is enclosed by a metal surface 72 having no mechanism (neither connection pads nor electrodes each surrounded by insulation material) for limiting solder flowing of a melted bump. The first embodiment of the method comprises:

forming at least a bump 3 (such as alloy of 63 tin/37 lead, with melting point of 183° C.), the bump 3 jutting out from the electrode 26;

forming at least a bump 5 (such as alloy of 90 lead/10 tin, with melting point of 220° C., which is shown in FIG. 3), the bump 5 jutting out from the metal surface 72 and having its melting point higher than that of the bump 3;

arranging the chip 2 and the lead frame 7 in such a way that the bump 3 and the bump 5 face and approach (or contact) each other; and

providing heat (reflow soldering the bump of lower melting point, i.e., reflow soldering bump 3, for example) until bump 3 melts as a result of the temperature of bump 3 reaching the melting point of bump 3, while the temperature of bump 5 remains below the melting point of bump 5 and bump 5 does not melt, thereby bump 3 melts to flow along the surface of bump 5 and to gradually surround surface of the bump 5, while bump 5 approaches the electrode 26 to eventually have one end 58 thereof on the electrode 26, or contact the electrode 26 when bump 3 is fully melted, resulting in an interconnection portion (shown in FIG. 6) including a first part 3 (melted bump 3 which may be cooled afterwards) and a second part 5 (bump 5 remaining in the same size or shape), the first part 3 having one end 37 on the metal surface 72 and another end 38 on the chip 2, the second part 5 having one end 57 on the metal surface 72 and another end 58 on the electrode 26 of the chip 2, the first part 3 and/or the second part being so composed that the melting point of the first part is lower than that of the second part 5, and the solder wettability between the first part 3 and the second part 5 is controlled by the second part 5 in case the first part 3 is in a fluid state, thereby the first part, when melted, surrounds and adheres to the surface of the second part. Although the first part 3 shown in FIG. 6 is in the shape of a circular cylinder with diameter at its ends 37 and 38 bigger than those at the other portions (particularly those at the portions in the middle of the gap between the chip 2 and the metal surface 72), its structure is not necessarily limited to the one shown in the figure, neither is the structure of the interconnection portion.

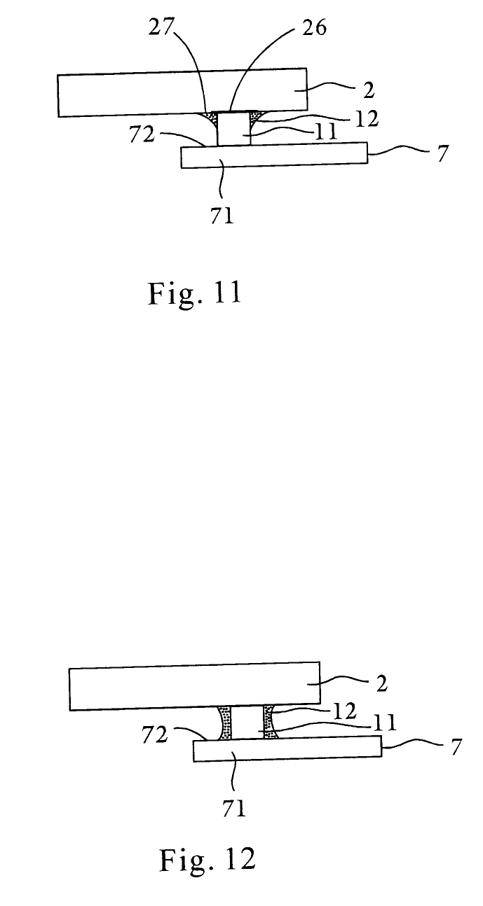

Specifically the end 38 of the first part 3 may partially contact the electrode 26 of the chip 2 and partially contact an area 27 which is part of a surface of the chip 2 and which surrounds the electrode 26 of the chip 2. Alternatively the end 38 of the first part 3 may fully contact the electrode 26 of the chip 2, or fully contact the area 27. Another alternative of the first part 3 may look like or the same as the melted and cooled connection medium 12 shown in FIG. 11. Because the second part 5 does not melt (i.e., remains in size/shape) and has one end on the metal surface 72 and another end on the electrode 26 of the chip 2, the distance between the electrode 26 of the semiconductor unit and the metal surface 72 is determined according to the size of the second part 5, resulting in avoidance of problems arising from bump collapse, leading to elimination of problems arising from the disunity of bumps' collapses inherent in conventional arts of connecting a chip to a device carrier (such as a lead frame) via bumps. If the bump 5 juts out from the metal surface 72 for a height 73, the distance between chip 2 (or specifically the electrode 26 of the chip 2) and the metal surface 72 is determined according to the height 73. Obviously bump 5 may be in permanent connection with chip 2 when the melted bump 3 gets cool as a result of ending the step of providing heat. In other words, bump 3 melts for bump 5 to approach chip 2, and to eventually have one end on chip 2, and further to be in permanent contact or connection with chip 2 when melted bump 3 gets cool.

According to the method provided by the present invention for connecting a semiconductor unit to a device carrier via bump, the solder wetty between the bump 3 and the bump 5 is essentially controlled by the bump 5 which has a higher melting point, and the bump 5 does not melt and shall not collapse, leading to the elimination of problems resulting from the disunity of bumps' collapses inherent in conventional art of connecting a semiconductor unit (such as a chip) to a device carrier (such as a lead frame) via bumps.

In the method provided by the present invention for connecting at least a semiconductor unit to a device carrier via bumps, the joint connection between bump 3 and bump 5 will be much better if soldering flux is spread on the surface of at least one of bumps 3 and 5. The spreading of soldering flux may be done before bumps 3 and 5 contact each other.

In the above method provided by the present invention for connecting at least a semiconductor unit to a device carrier (such as a lead frame) via bumps, lead frame with fine pitch can be achieved if the bump on the lead frame 7 is formed by plating, thereby the trend for related industries to minimize product size can be met.

The application of the method provided by the present invention for connecting at least a semiconductor unit to a device carrier via bumps is not limited to the connection between a chip 2 and a lead frame 7. In fact, the method provided by the present invention can be applied to the connection between a plurality of semiconductor units and a plurality of device carriers respectively via at least a bump, subjecting to only one condition: the solder wetty between the bump 3 and the bump 5 is essentially controlled by the bump 5 which has a higher melting point, thereby the melted bump 3 surrounds and adheres to the bump 5 instead of spreading onto the metal surface 72.

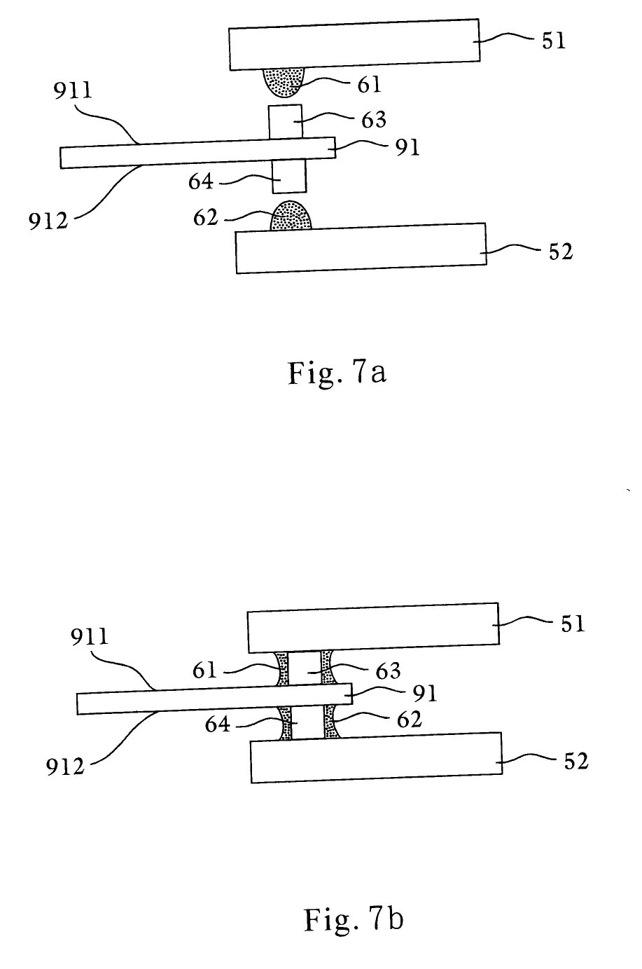

FIGS. 7a and 7b show an embodiment of a method provided by the present invention for connecting at least two semiconductor units (such as chips 51 and 52 in the figures) to a device carrier (such as lead frame 91 in the figures), wherein the semiconductor unit includes at least an electrode (the same as 26 shown in FIGS. 2-6, but not shown in FIGS. 7a-12), which comprises:

respectively forming chip bumps 61 and 62 on the electrodes of chips 51 and 52;

respectively forming lead frame bumps 63 and 64 on a first metal surface 911 and a second connection surface 912 of the lead frame 91, wherein the melting points of lead frame bumps 63 and 64 are respectively higher than those of chip bumps 61 and 62; arranging the chips 51 and 52 and the lead frame 91 in such a way that the lead frame bumps 63 and 64 respectively face and approach (or contact) the chip bumps 61 and 62; and

providing heat in such a way (reflow soldering chip bumps 61 and 62, for example) that the temperatures of chip bumps 61 and 62 respectively reaches at least the melting points of chip bumps 61 and 62, while the temperatures of bumps 63 and 64 respectively remain below the melting points of bumps 63 and 64, thereby bumps 63 and 64 will gradually be surrounded respectively by the melted bumps 61 and 62, and may respectively contact and connect the chips 51 and 52 (specifically the electrodes of the chips 51 and 52) when the bumps 61 and 62 are fully melted as a result of providing heat thereto. Obviously bumps 63 and 64 may be in permanent connection respectively with chips 51 and 52 when the melted bumps 61 and 62 get cool as a result of ending the step of providing heat. In other words, bumps 61 and 62 melt for bumps 63 and 64 to respectively approach chips 51 and 52, and eventually contact and connect chips 51 and 52. It can be seen from FIG. 7b that two interconnection portions are respectively formed between lead frame 91 and chips 51/52, wherein the one including a first part 61 and a second part 63 has one end (not numerically marked in the figures) on the metal surface 911 and another end (not numerically marked in the figures) on chip 51, and the one including a first part 62 and a second part 64 has one end (not numerically marked in the figures) on the metal surface 912 and another end (not numerically marked in the figures) on chip 52.

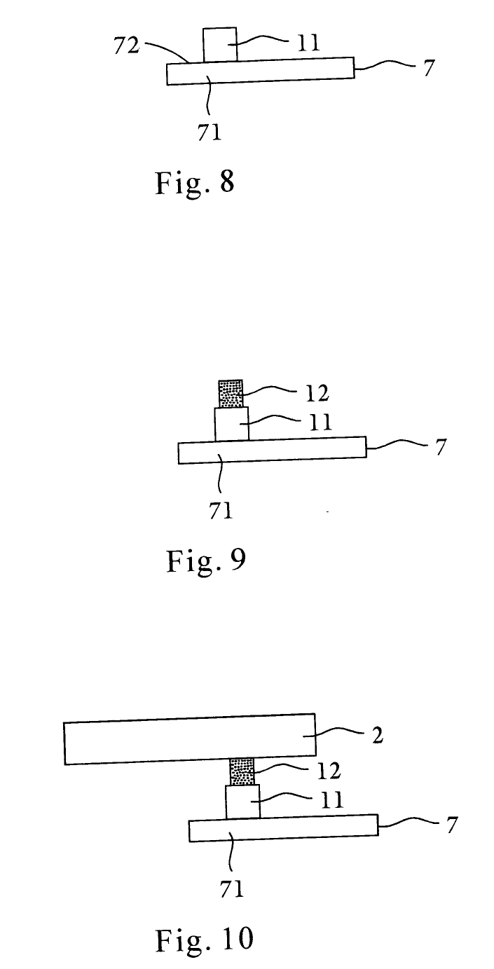

FIGS. 8, 9, 10, 11, 12 show a further embodiment of a method provided by the present invention for connecting a semiconductor unit (such as chip 2 in FIG. 10) to a device carrier (such as lead frame 7 in the figures), which comprises:

forming a bump (such as the bump 11 in FIG. 8) on a metal surface 72 of the inner lead 71 of lead frame 7;

placing a connection medium 12 on bump 11 as shown in FIG. 9, followed by arranging a chip 2 in such a way that a portion of the chip 2 for electrical connection (or only for mechanical connection) contacts the connection medium 12, i.e., sandwiching the connection medium 12 between the bump 11 and the chip 2, as shown in FIG. 10; and providing heat (reflow soldering the connection medium 12, for example) in such a way that the temperature of connection medium 12 reaches at least the melting point of connection medium 12 while the temperatures of bump 11 and chip 2 respectively remain below the melting points of bump 11 and chip 2. For example, reflow solder connection medium 12 with a temperature which equals or exceeds the melting point of connection medium 12 while remains below the melting points of bump 11 and chip 2. The connection medium 12 will melt while bump 11 and chip 2 will not (or shall remain the same) under this condition, thereby bump 11 will gradually be surrounded by melted connection medium 12, and may eventually approach or contact chip 2 as shown in FIG. 12, resulting in an interconnection portion (shown in FIG. 12) including a first part 12 and a second part 11, both the first part 11 and second part 12 have one end on the metal surface 72 of the inner lead 71 of lead frame 7 and another end on chip 2. It can be seen the distance between the metal surface 72 of the inner lead 71 of lead frame 7 and chip 2 is determined by the size (specifically the height) of bump 11 which has not melted or has remained the same, resulting in avoidance of problems arising from bump collapse, leading to elimination of problems arising from the disunity of bumps' collapses inherent in conventional arts of connecting a chip to a device carrier (such as lead frame) via bumps.

While the invention has been described on the basis of what are presently considered to be the most practical and preferred embodiments, it shall be understood that the invention is not limited to the disclosure. On the contrary, it is to cover various modifications and similar arrangements included within the spirit and scope of the claims.

What is claimed is:

1. A method for connecting at least a semiconductor unit to at least a device carrier wherein said semiconductor unit includes at least an electrode and said device carrier includes a metal surface, said method comprising:
forming at least a bump of a first type, the bump of said first type jutting out from the electrode of said semiconductor unit and having a first melting point;
forming at least a bump of a second type, the bump of said second type jutting out from said metal surface and having a second melting point higher than said first melting point;
arranging said semiconductor unit and said device carrier in such a way that the bump of said first type and the bump of said second type face and approach each other;
providing heat until the bump of said first type reaches a temperature at least equal to said first melting point, while the bump of said second type remains at a temperature lower than said second melting point; and
letting the bump of said first type melt for the bump of said second type to approach the electrode of said semiconductor unit until the bump of said second type has one end on the electrode of said semiconductor unit.

2. The method according to claim 1 wherein said device carrier is a lead frame.

3. The method according to claim 1 further comprising letting the melted bump of said first type flow to surround the bump of said second type and to reach a first end of the bump of said second type, wherein the first end of the bump of said second type is on said metal surface, thereby said semiconductor unit connects said device carrier via the bump jutting out from said metal surface which is free from requiring mechanism thereon for limiting solder flowing of the melted bump.

4. The method according to claim 1 further comprising letting the distance between said metal surface and the electrode of said semiconductor unit be determined according to the size of the bump of said second type.

5. The method according to claim 4 wherein the bump of said second type juts out from said metal surface for a height, and the distance between the electrode of said semiconductor unit and said metal surface is determined by said height.

6. The method according to claim 1 wherein the bump of said second type is formed by stencil printing.

7. The method according to claim 1 wherein the bump of said second type is formed by plating.

8. The method according to claim 1 further comprising letting the solder wettability between the melted bump of said first type and the bump of said second type be controlled by the bump of said second type, thereby the melted bump of said first type surrounds and adheres to the bump of said second type instead of spreading onto said metal surface.

9. The method according to claim 1 wherein the bump of said first type is fully melted for the bump of said second type to contact the electrode of said semiconductor unit.

10. The method according to claim 1 wherein the bump of said first type is an alloy including more tin than lead while the bump of said second type is an alloy including more lead than tin.

11. A method for connecting at least a semiconductor unit to at least a device carrier wherein said semiconductor unit includes at least an electrode and said device carrier is enclosed by a metal surface, said method comprising:
forming at least a bump of a first type, the bump of said first type jutting out from the electrode of said semiconductor unit and having a first melting point;
forming at least a bump of a second type, the bump of said second type jutting out from said metal surface and having a second melting point higher than said first melting point;
arranging said semiconductor unit and said device carrier in such a way that the bump of said first type and the bump of said second type contact each other;
providing heat until the bump of said first type reaches a temperature at least equal to said first melting point, while the bump of said second type remains at a temperature lower than said second melting point; and
letting the bump of said first type melt for the bump of said second type to approach the electrode of said semiconductor unit until the bump of said second type contacts the electrode of said semiconductor unit, thereby said semiconductor unit connects said device carrier via the bump jutting out from said metal surface which is free from requiring mechanism thereon for limiting solder flowing of melted metal.

12. An electronic package comprising:
a device carrier including a metal surface;
at least a semiconductor unit including at least an electrode; and
at least an interconnection portion including a first part and a second part, said first part having one end on said metal surface and another end on said semiconductor unit, said second part having one end on said metal surface and another end on the electrode of said semiconductor unit, said first part having a melting point lower than that of said second part and surrounding and adhering to said second part.

13. The electronic package according to claim 12 wherein said interconnection portion electrically connects said metal surface and said semiconductor unit.

14. The electronic package according to claim 12 wherein said interconnection portion mechanically connects said device carrier and said semiconductor unit.

15. The electronic package according to claim 12 wherein said first part contains more tin than lead, while said second part contains more lead than tin.

16. The electronic package according to claim 12 wherein said device carrier is a lead frame.

17. The electronic package according to claim 12 wherein said device carrier is a lead frame including an inner lead enclosed by said metal surface.

18. The electronic package according to claim 12 wherein said second part contains materials for controlling the solder wettability between said first part and said second part in case said first part is in a fluid state.

19. The electronic package according to claim 12 wherein said first part contains materials for the solder wettability between said first part and said second part be controlled by said second part in case said first part is in a fluid state.

20. The electronic package according to claim 12 wherein said another end of said first part partially contacts the electrode of said semiconductor unit and partially contacts an area which is part of said semiconductor unit and which surrounds the electrode of said semiconductor unit.
